(19) United States
(12) Patent Application Publication
(10) Pub. No.: US 2007/0151842 A1
(43) Pub. Date: Jul. 5, 2007

(54) APPARATUS FOR REACTIVE SPUTTERING

(75) Inventors: Richard DeVito, Saugus, MA (US); Martin Klein, Bedford, MA (US); Piero Sferlazzo, Marblehead, MA (US)

Correspondence Address: RAUSCHENBACH PATENT LAW GROUP, LLC, P.O. BOX 387, BEDFORD, MA, 01730, US

(73) Assignee: FLUENS CORPORATION, Billerica, MA (US)

(21) Appl. No.: 11/610,665

(22) Filed: Dec. 14, 2006

Related U.S. Application Data
(60) Provisional application No. 60/750,668, filed on Dec. 15, 2005.

(51) Int. Cl. C23C 14/00; C23C 14/32

(52) U.S. Cl. 204/192.1; 204/298.02

(57) ABSTRACT

A reactive sputtering system includes a vacuum chamber and a reactive ion source that is positioned inside the vacuum chamber. The reactive ion source generates a reactive ion beam from a reactant gas. A sputtering chamber is positioned in the vacuum chamber. The sputtering chamber includes a sputter source having a sputtering target that generates sputtering flux, walls that contain an inert gas, and a seal that impedes the reactant gas from entering into the sputtering chamber and that impedes inert gas and sputtered material from escaping into the vacuum chamber. A transport mechanism transports a substrate under the reactive ion source and through the sputtering chamber. The substrate is exposed to the reactive ion beam while passing under the reactive ion source and then is exposed to sputtering flux while passing through the sputtering chamber.

### RELATED APPLICATION SECTION

This application claims priority to U.S. Provisional Patent Application Ser. No. 06/750,668, filed Dec. 15, 2005, entitled “Apparatus for Reactive Sputtering,” the entire application of which is incorporated herein by reference.

The section headings used herein are for organizational purposes only and should not to be construed as limiting the subject matter described in the present application.

### BACKGROUND

Sputtering is widely used in many industries to deposit dielectrics, such us oxides and nitrides (e.g. Al₂O₃, AlN). These dielectrics are used for a variety of applications, such as optical coatings, electronic and optical device fabrication, and for other devices, such as thin film head for computer hard drives. There are many known methods of sputtering.

One method of sputtering dielectrics is radio frequency (RF) sputtering. Two commonly used methods of RF sputtering are RF diode and RF magnetron sputtering of dielectric targets. RF sputtering has a relatively low deposition rate because sputter yields are relatively low for dielectric target materials. Sputtering yields of dielectric materials are typically much lower than sputtering yields of metals because sputtering of dielectric materials is relatively inefficient.

Another method of sputtering is direct current (DC) sputtering. Yet another method of sputtering is pulsed DC magnetron sputtering. Pulsed DC magnetron sputtering is sometimes used with reactive gases to perform reactive sputtering of metal/semiconductor targets in the presence of a reactant, such as oxygen and nitrogen.

### BRIEF DESCRIPTION OF THE DRAWINGS

The aspects of this invention may be better understood by referring to the following description in conjunction with the accompanying drawings, in which like numerals indicate like structural elements and features in various figures. The drawings are not necessarily to scale. The skilled artisan will understand that the drawings, described below, are for illustration purposes only. The drawings are not intended to limit the scope of the present teachings in any way.

FIG. 1A illustrates a perspective view diagram of a reactive sputtering system according to the present invention with the vacuum chamber top in the open position.

FIG. 1B illustrates a perspective view diagram of the reactive sputtering system described in connection with FIG. 1A with the vacuum chamber top in the closed position.

FIG. 2A illustrates a cross sectional diagram of a reactive sputtering system according to the present invention.

FIG. 2B illustrates a cross sectional diagram of a sputtering chamber for the reactive sputtering system according to the present invention.

FIG. 2C illustrates a cross sectional diagram of the sliding seal according to the present invention.

### DETAILED DESCRIPTION

While the present teachings are described in conjunction with various embodiments and examples, it is not intended that the present teachings be limited to such embodiments. On the contrary, the present teachings encompass various alternatives, modifications and equivalents, as will be appreciated by those of skill in the art. For example, some aspects of the methods and apparatus of the present invention are described in connection with depositing Al₂O₃ or AlN thin films. It should be understood that the methods and apparatus of the present invention can be applied to forming an almost unlimited number of thin films by reactive sputtering.

It should be understood that the individual steps of the methods of the present invention may be performed in any order and/or simultaneously as long as the invention remains operable. Furthermore, it should be understood that the apparatus of the present invention can include any number or all of the described embodiments as long as the invention remains operable.

The deposition rate of reactive sputter is determined by two competing phenomena. One phenomena is that high reactant partial pressures are needed to achieve high sputtering rates because high reactant partial pressures are generally required to complete the necessary dielectric reaction of the growing films. The second phenomena is that high partial pressures of reactants induce a dielectric film formation on the target itself, and also on the exposed metallic surface exposed. These induced dielectric film formations can dramatically limit the deposition rates. In addition, these induced dielectric film formations can cause instabilities which can result in the formation of electrical discharges that can damage the sputtering system and/or the surface being processed. In addition, these induced dielectric formations can result in an unpredictable deposition rate.

A reactive sputtering apparatus of the present invention maintains high reaction rates at the surface of the substrate and, therefore high growth rates, while simultaneously reducing or eliminating dielectric film producing reactions on the target and on the anode surfaces of the magnetrons. One embodiment of the reactive sputtering apparatus of the present invention includes at least one physical barrier that is formed between the substrate and the target which prevents reactants from flowing proximate to the target and to the magnetron, while still enabling the substrate to be exposed to high levels of reactants.

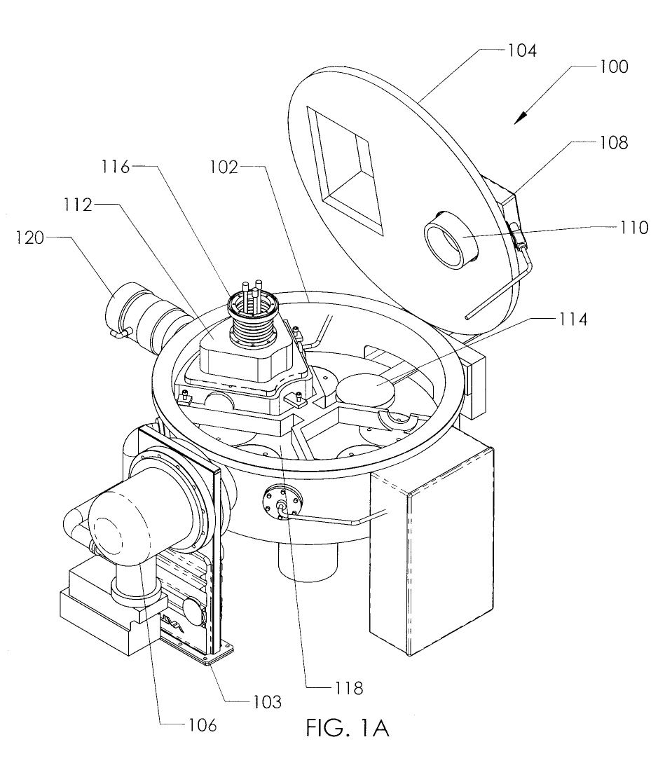

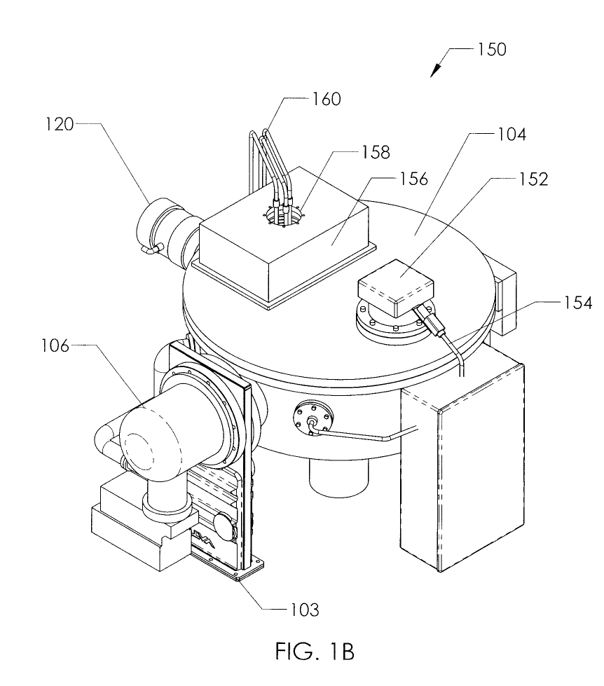

FIG. 1A illustrates a perspective view diagram of a reactive sputtering system 100 according to the present invention with the vacuum chamber top in the open position. The reactive sputter system 100 includes a vacuum chamber 102 having a lid or top 104 that is in the closed position. A first or primary vacuum pump 106 has an input that is coupled to the vacuum chamber 102. The first vacuum pump 106 pumps the vacuum chamber 102 to reduce the pressure in the vacuum chamber 102 and to maintain the pressure at the desired operating pressure. A gate valve 103 is positioned between the first vacuum pump 106 and the vacuum chamber 102 so as to control the conductance between the first vacuum pump 106 and the vacuum chamber 102.

A reactive ion source 108 is positioned with an output 110 inside the vacuum chamber 102. The reactive ion source 108 generates a reactive ion beam from a reactant gas. In some embodiments, more than one reactant gas and/or a reactive gas and an inert gas is used to generate the reactant ion beam. In these embodiments, at least two mass flow controllers are used to provide at least two feed gases to the reactive ion source 108.

In some embodiments, the reactive ion source 108 is a radical ion source that is remotely positioned relative to the vacuum chamber 102 as shown in FIG. 1. In these embodiments, the output 110 of the reactive ion source 108 is coupled to the vacuum chamber 102 so that the reactive ions flow downstream from the remotely positioned radical ion source into the vacuum chamber 102. In other embodiments, the reactive ion source 108 is positioned entirely in the vacuum chamber 102.

In some embodiments, the reactive ion source 108 includes a grid for extracting the reactive ion beam at a uniform predetermined energy. In other embodiments, the reactive ion source is a gridless ion source. In one specific embodiment, the reactive ion source 108 comprises a linear ion source. In another specific embodiment, the reactive ion source comprises a combination of at least two circular ion sources that generate a desired overlapping ion beam pattern. For example, the overlapping ion beam pattern can be chosen to improve the uniformity or to increase the ion density of the combined ion beam pattern.

A sputtering chamber 112 is positioned in the vacuum chamber 102. The sputtering chamber 112 is a chamber within the vacuum chamber 102 that contains an inert gas environment that is isolated from the ion source environment and from other area of the vacuum chamber. In one embodiment, the sputtering chamber 112 comprises a delta shaped chamber. In this embodiment, the dimensions of the delta shaped sputtering chamber are chosen so as to maintain a constant sputtering flux at the surface of the substrate 114 transporting through the sputtering chamber 112 typically at a constant rotation rate.

A sputter source 116 is positioned in communication with the sputtering chamber 112. One skilled in the art will appreciate that numerous types of sputtering sources can be used with the present invention. For example, the sputtering source 116 can be a magnetron sputtering source as shown in FIG. 1, which is commonly used in the industry. The sputtering source 116 can be located inside the sputtering chamber 112 or can be attached to a top surface of the sputtering chamber 112.

The walls of the sputtering chamber 112 are designed to contain the inert gas used for sputtering and are also designed to prevent reactive gas that is present in other sections of the vacuum chamber from passing into the sputtering chamber 112. A second vacuum pump 120 has an input that is coupled to at least one of the sputtering chamber 112 and a differential sliding seal as described herein. The sputtering source 116 includes a sputtering target. In some embodiments, the sputtering target in the sputtering source 116 is a metal sputtering target or is formed of at least some metal materials. The sputter source 116 generates sputtering flux from the sputtering target.

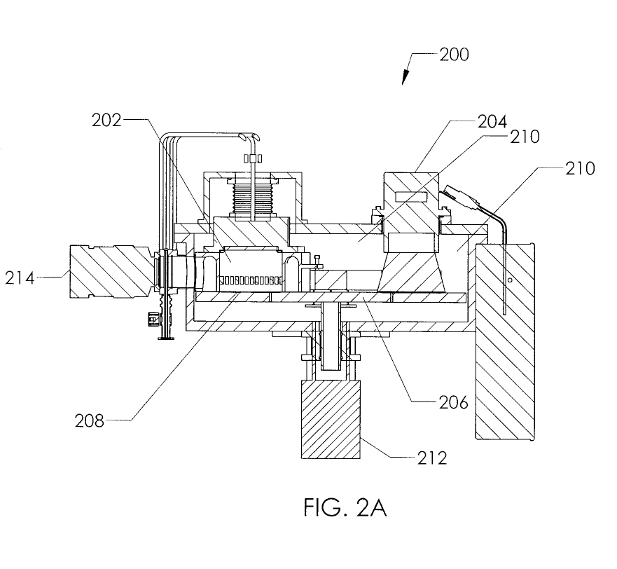

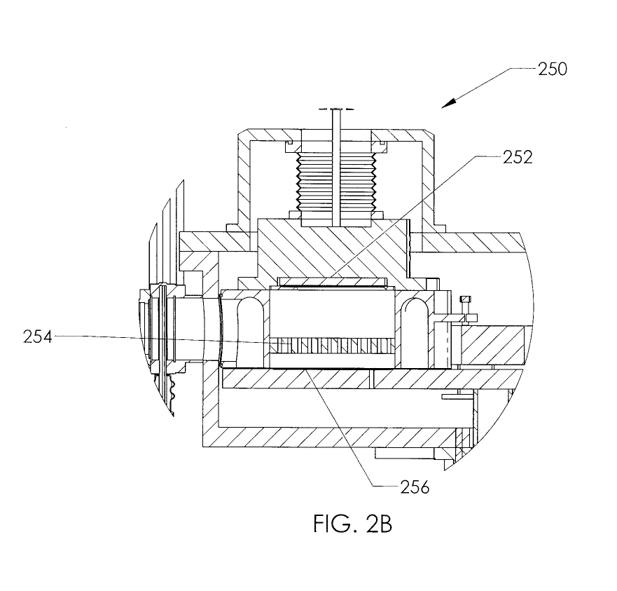

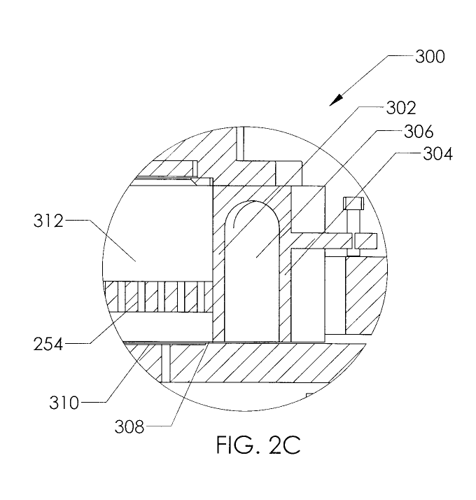

In one embodiment, an aperture is positioned in the path of the sputtering flux to improve the uniformity of the deposited sputtered material. In many applications, directional deposition is desirable or required. Thus, in one embodiment, the sputtering flux is collimated. One skilled in the art will appreciate that there are numerous means for achieving collimation of the sputtering flux. In one embodiment, a mechanical collimator is positioned between the sputtering target and the substrate 114 to control the direction of the sputtering flux as shown in FIGS. 2A and 2B.

In one embodiment, the sputter source 116 is designed to achieve natural collimation. It is known in the art that at low pressures, some degree of collimation can be achieved by properly selecting the sputtering parameters. For example, it is known in the art that some degree of collimation can be achieved by increasing the target-to-substrate distance. In other embodiments, natural collimation is combined with a means of physical collimation, such as the use of a mechanical collimator as described herein to achieve the desired sputtering flux directionality.

A transport mechanism 118 is used to transport the substrate 114 or multiple substrates under the reactive ion source 108 and through the sputtering chamber 112. In one embodiment, the transport mechanism 118 is a rotating dial or disk that is positioned in the vacuum chamber 102 as shown in FIG. 1. The transport mechanism 118 moves the substrate 114 under the reactive ion beam where the substrate 114 is exposed to the reactive ion beam flux.

The transport mechanism 118 then moves the substrate 114 through the sputtering chamber 112 where the transport mechanism 118 forms a bottom surface of the sputtering chamber 112. The substrate 114 is exposed to the sputtering flux so that a layer of sputtering target material forms on the surface of the substrate 114. The substrate 114 then transports out of the sputtering chamber 112 and back into the reactive gas environment and under the ion source 108. The processes of transporting the substrate 114 under the reactive ion beam and then through the sputtering chamber 112 is typically repeated numerous times.

One aspect of the reactive sputtering apparatus of the present invention is that the sputter deposition is decoupled from the reactive ion beam processing by using at least one seal. The term “seal” is defined herein as any means of preventing the reactive gas from entering into the sputtering chamber 112. In many embodiments, however, the seal also contains the inert gas and sputtered material in the sputtering chamber 112. It should be understood that the at least one seal does not have to be a physical barrier. In some embodiments, the at least one seal is a gas curtain. One skilled in the art will appreciate that many types of seals can be used in the reactive sputter apparatus of the present invention.

In many embodiments, at least one seal is a sliding seal that maintains a vacuum seal while sliding. In one particular embodiment, at least one seal comprises a differentially pumped sliding seal. A transport mechanism with a differentially pumped sliding seal is described in U.S. Pat. No. 6,972,055, to Sferlazzo, entitled “Continuous Flow Deposition System,” which is assigned to the present assignee. The entire specification of U.S. Pat. No. 6,972,055 is incorporated herein by reference. In this particular embodiment, the second vacuum pump 120 is used to control the pressure in the region between the inner and outer wall of the seal as described in connection with FIG. 3C.

In some embodiments, at least one seal comprises a sliding seal that is not differentially pump. In these embodiments, the second vacuum pump 120 (or another vacuum pump) is positioned with an input that is coupled inside the sputtering chamber 112. The second vacuum pump (or other vacuum pump) is used to control the pressure in the sputtering chamber 112. Yet other embodiments can include both a differentially pumped sliding seal and a vacuum pump that is directly connected inside the sputtering chamber 112.

The sliding seal and the differentially pumped sliding seal isolate the target from the reactive gas, thereby preventing the target material from reacting with the reactive gas. At the same time, the sliding seal confines the sputtered target material within the sputtering chamber 112, thus preventing any interactions of the sputtered material with the reactive gas.

FIG. 1B illustrates a perspective view diagram of the reactive sputtering system 150 described in connection with FIG. 1A with the vacuum chamber top in the closed position (i.e. under vacuum). Referring to both FIGS. 1A and 1B, the perspective view shows the top 104 sealing the vacuum chamber 102. Also, the perspective view shows the top 152 of the reactive ion source 108 including the reactive gas feed line 154. In addition, the perspective view shows the top 156 of the sputtering chamber 112 and the top 158 of the sputtering source 116 with the inert gas feed lines 160.

FIG. 2A illustrates a cross sectional diagram of a reactive sputtering system 200 according to the present invention. The cross sectional diagram of the reactive sputtering system 200 illustrates many features not shown in the perspective views. Specifically, FIG. 2A illustrates a cross section of the sputtering chamber 202, the reactive ion source 204, and the transport mechanism 206. The cross section shows how the transport mechanism 206 transports a substrate 208 or multiple substrates in the vacuum chamber 210 under the reactive ion source 204 and through the sputtering chamber 202. In addition, FIG. 2A illustrates a cross section of the first vacuum pump 212 showing where the first vacuum pump 212 couples into the vacuum chamber 210 and a cross section of the second vacuum pump 214 showing where the second vacuum pump couples into the sputtering chamber 202.

FIG. 2B illustrates a cross sectional diagram of a sputtering chamber 250 for the reactive sputtering system according to the present invention. FIG. 2B shows the sputtering target 252 and a mechanical collimator 254 that is positioned between the sputtering target 252 and a substrate 256. The mechanical collimator 254 can be used to control the direction of the sputtering flux. In one embodiment, the mechanical collimator 254 is a metallic plate with an array of holes as shown in FIG. 2B. The degree of collimation in one dimension that can be achieved is a function of the ratio of the diameter of the holes in the metallic plate to the length of the array of holes.

FIG. 2C illustrates a cross sectional diagram of the sliding seal 300 according to the present invention. The differentially pumped sliding seal 300 includes an inner wall 302 and an outer wall 304 with an open region 306 between the inner wall 302 and the outer wall 304 of the seal 300. The second vacuum pump 214 (FIG. 2A) is coupled to the open region 306 of the sliding seal 300 in order to control the pressure between the inner wall 302 and the outer wall 304 of the seal 300.

The gap between the inner wall 302 and the outer wall 304 is relatively small. In one specific embodiment, the gap between the inner wall 302 and the outer wall 304 is about 1 mm or less. In addition, the gap 314 between the substrate 310 and inner wall 302 of the seal 300 is also relatively small.

In operation, the second vacuum pump 214 (FIG. 2A) evacuates the open region 306 of the sliding seal 300 to evacuate the area between the inner wall 302 and the outer wall 304 of the seal 300. The evacuation, in addition to the small gap 308 between the substrate 310 and the inner wall 302 of the seal 300, isolates the environment inside of the sputter chamber 312 from the rest of the vacuum chamber 210 (FIG. 2A). This isolation prevents the reactive gas in the vacuum chamber 210 from entering the sputter chamber 312 and also prevents the inert gas and stray sputtered metal from entering the reactive gas environment of the vacuum chamber 210.

In another embodiment, the seal comprises a gas curtain seal. Gas curtain seals are described in, for example, U.S. Patent Published Patent Application No. 2003/0194493 A1 to Chang et al., entitled “Multi-Station Deposition Apparatus and Method.” In this embodiment, a vertical curtain of purge gas is used to isolate gases within the adjacent areas of the vacuum chamber.

A method of operating the reactive sputtering source of the present invention to sputter films, such as Al₂O₃ or AlN, includes generating a reactive ion beam from a reactive gas in the vacuum chamber 102. In some processes, the volume of gas proximate to the sputter source 116 is evacuated with the vacuum pump 106 (or another vacuum pump).

In some embodiments, the reactive ion beam is generated remotely from the vacuum chamber 102 as shown in FIG. 1. Generating the reactive ion beam remotely is desirable for some processes because the parameters for generating the reactive ions can be essentially decoupled from the other downstream processing parameters, such as the pressure at the substrate. Such decoupling provides independent control of the reactive ion beam parameters and the other processing parameters. Also, in some embodiments, the reactive ion beam is extracted through a grid so that the ions achieve a desired relatively uniform and predetermined energy.

In some processes according to the present invention, the reactive ion beam is an oxygen ion beam that is formed from relatively pure oxygen. The resulting oxygen ion beams can be used to perform at least one of oxidation and densification of the deposited sputtered material. In other processes, the reactive ion beam is formed from both oxygen and an inert gas, such as argon. The resulting oxygen/argon ion beam performs at least one of oxidation and densification of the deposited sputtered material. In addition, the resulting oxygen/argon ion beam can have an argon (or other inert gas) content that is chosen to change the properties of the sputtered film. For example, the percentage of argon (or other inert gas) can be chosen to reduce the hardness of the sputtered film.

An inert gas, such as argon, is injected into to the sputter source 116 and is substantially contained within the walls of the sputter source. The inert gas injected in the sputter source impedes the reactant gas and other gases from entering into the sputter source. Sputtering flux is generated from the inert gas contained within the sputter source 116. In one embodiment, the generated sputtering flux is a metal sputtering flux. For example, the sputtering flux can be an aluminum sputtering flux. In some embodiments, the sputtering flux is collimated to control a direction of the sputtering flux. In some embodiments, the shape of an aperture positioned in a path of the sputtering flux is adjusted to improve uniformity of the deposited sputtered material.

The substrate 114 is then transported in the vacuum chamber 102 under the reactive ion beam and through the sputtering chamber 112 in a desired sequence that is determined by the user. One skilled in the art will appreciate that there are many possible sequences of transporting the substrate 114 under the reactive ion beam and through the sputtering chamber 112. In some embodiments, substrates are initially pre-cleaned or otherwise pretreated with the reactive ion beam to active the substrate for deposition of the sputtered material.

After substrate pretreatment (if substrate pretreatment is desired), the substrate 114 is transported into the sputtering chamber 112, thereby exposing the substrate 114 to the sputtering flux so that a film of sputtered material is deposited on the surface of the substrate 114. For example, if the target material is aluminum, an aluminum film is deposited on the surface of the substrate 114.

The substrate 114 with the newly formed thin film is then rotated out of the sputtering chamber 112 and into the reactive gas environment and under the reactive ion beam. The reactive ions impacting the surface of the newly formed thin film react with the sputtered material in the newly formed thin film, thereby forming a new compound on the surface of the substrate 114. For example, if the sputtered material is aluminum and the reactive gas is oxygen, the newly formed material will be aluminum oxide.

In many embodiments, the process is repeated in a periodic manner with the substrate 114 rotating at a substantially constant rate of rotation. However, there are many variations of the process according to the present invention. For example, the rate of rotation when the substrate 114 passes under the reactive ion beam can be different from the rate of rotation when the substrate 114 passes through the sputtering chamber 112.

In many embodiments, sputtering parameters, such as the energy of reactive ions and the current density of the reactive ion beam are selected to achieve certain types of films. It is understood that parameters, such as the energy of reactive ions in the reactive ion beam and the current density of the reactive ion beam can be selected to achieve both certain sputtered film properties and certain types of films. For example, in some embodiments, at least one of the energy of reactive ions in the reactive ion beam and the current density of the reactive ion beam is chosen to oxidize a single monolayer of deposited sputtered material as the substrate 114 is transported through the reactive ion beam.

In addition, in many embodiments, sputtering parameters, such as the energy of reactive ions and the current density of the reactive ion beam are selected to achieve certain sputtered film properties. It is understood that parameters, such as the energy of reactive ions in the reactive ion beam and the current density of the reactive ion beam can be selected to simultaneously achieve multiple sputtered film properties.

For example, in one embodiment, at least one of the energy of reactive ions in the reactive ion beam and the current density of the reactive ion beam is selected to obtain a desired stress of the deposited sputtered material. In one specific embodiment, at least one of the energy of reactive ions in the reactive ion beam and the current density of the reactive ion beam is chosen to reduce compressive forces in the deposited sputtered material.

Also, in one embodiment, at least one of the energy of reactive ions in the reactive ion beam and the current density of the reactive ion beam is chosen to obtain a desired refractive index of the deposited sputtered material. In addition, in some embodiments, at least one of the energy of reactive ions in the reactive ion beam and the current density of the reactive ion beam is chosen to increase oxidization of the deposited sputter material.

Thin films sputtered with the reactive sputtering apparatus of the present invention using an oxygen or an oxygen/argon reactive ion beam and an inert argon gas for sputtering have relatively low concentrations of argon gas incorporation into the film. In one embodiment, the gas mixture is chosen to sputter a film with a desired hardness. For example, the hardness of some films can be reduced by adding predetermined quantity of argon into the ion source. In one specific process, a mixture of 90% oxygen and 10% argon is injected into the ion source to control the hardness of the sputtered film to a desired hardness.

### EQUIVALENTS

While the present teachings are described in conjunction with various embodiments and examples, it is not intended that the present teachings be limited to such embodiments. On the contrary, the present teachings encompass various alternatives, modifications and equivalents, as will be appreciated by those of skill in the art, may be made therein without departing from the spirit and scope of the invention as defined by the appended claims.

What is claimed is:

1. A reactive sputtering system comprising:
a) a vacuum chamber;
b) a reactive ion source that is positioned inside the vacuum chamber, the reactive ion source generating a reactive ion beam from a reactant gas;
c) a sputtering chamber that is positioned in the vacuum chamber, the sputtering chamber comprising a sputter source having a sputtering target that generates sputtering flux, walls that contain an inert gas, and a seal that impedes the reactant gas from entering into the sputtering chamber and that impedes inert gas and sputtered material from escaping into the vacuum chamber; and
d) a transport mechanism that transports a substrate under the reactive ion source and through the sputtering chamber, the substrate being exposed to the reactive ion beam while passing under the reactive ion source and being exposed to sputtering flux while passing through the sputtering chamber.

2. The reactive sputtering system of claim 1 wherein the reactive ion source comprises a radical ion source that is remotely positioned relative to the vacuum chamber.

3. The reactive sputtering system of claim 1 wherein the reactive ion source comprises a grid for extracting the reactive ion beam at a predetermined energy.

4. The reactive sputtering system of claim 1 wherein the reactive ion source comprises a gridless ion source.

5. The reactive sputtering system of claim 1 wherein the reactive ion source comprise a linear ion source.

6. The reactive sputtering system of claim 1 wherein the reactive ion source comprises a combination of at least two circular ion sources with a desired overlapping ion beam pattern.

7. The reactive sputtering system of claim 1 wherein the seal comprises a sliding seal.

8. The reactive sputtering system of claim 1 wherein the seal comprises a gas curtain seal.

9. The reactive sputtering system of claim 1 further comprising a vacuum pump that is positioned with an input inside the sputtering chamber, wherein the vacuum pump controls a pressure inside the sputtering chamber.

10. The reactive sputtering system of claim 1 wherein the seal is differentially pumped.

11. The reactive sputtering system of claim 1 wherein the seal comprises an inner wall and an outer wall containing a volume of gas.

12. The reactive sputtering system of claim 11 further comprising a vacuum pump that is coupled to the volume of gas between the inner wall and the outer wall of the seal so as to evacuate the volume of gas to a desired pressure.

13. The reactive sputtering system of claim 1 wherein the sputtering source comprises a magnetron sputtering source.

14. The reactive sputtering system of claim 1 wherein the sputtering target comprise a metal sputtering target.

15. The reactive sputtering system of claim 1 wherein the transport mechanism comprises a rotating disk that supports at least one substrate to be processed.

16. The reactive sputtering system of claim 1 wherein the sputtering chamber comprises a delta shaped chamber.

17. The reactive sputtering system of claim 1 further comprising an aperture positioned in a path of the sputtering flux that improves uniformity of the deposited sputtered material.

18. The reactive sputtering system of claim 1 further comprising a collimator positioned between the sputtering target and the substrate, the collimator controlling the direction of the sputtering flux.

19. A method of reactive sputtering, the method comprising:
a) generating a reactive ion beam from a reactive gas in a vacuum chamber;
b) containing an inert gas within a sputter source positioned inside the vacuum chamber so as to impede the reactant gas from entering into the sputter source;
c) generating sputtering flux from the inert gas contained within the sputter source; and
d) transporting a substrate through the reactive ion beam and through the sputtering flux in the sputter source, thereby reacting the reactive ions with sputtered material deposited on the substrate.

20. The method of claim 19 wherein the generating the reactive ion beam comprises generating an oxygen ion beam that performs at least one of oxidation and densification of the deposited sputtered material.

21. The method of claim 19 wherein the generating the reactive ion beam comprises generating an oxygen and argon ion beam that perform at least one of oxidation and densification of the deposited sputtered material.

22. The method of claim 19 wherein the generating the sputtering flux comprises generating metal sputtering flux.

23. The method of claim 22 wherein the metal sputtering flux comprises aluminum sputtering flux.

24. The method of claim 19 further comprising pre-cleaning the substrate with the reactive ion beam to active the substrate for deposition of the sputtered material.

25. The method of claim 19 further comprising selecting at least one of an energy of reactive ions in the reactive ion beam and a current density of the reactive ion beam to obtain a desired stress of the deposited sputtered material.

26. The method of claim 19 further comprising selecting at least one of an energy of reactive ions in the reactive ion beam and a current density of the reactive ion beam to reduce compressive forces in the deposited sputtered material.

27. The method of claim 19 further comprising selecting at least one of an energy of reactive ions in the reactive ion beam and a current density of the reactive ion beam to obtain a desired refractive index of the deposited sputtered material.

28. The method of claim 19 further comprising selecting at least one of an energy of reactive ions in the reactive ion beam and a current density of the reactive ion beam to oxidize a single monolayer of deposited sputtered material as the substrate is transported through the reactive ion beam.

29. The method of claim 19 further comprising selecting at least one of an energy of reactive ions in the reactive ion beam and a current density of the reactive ion beam to increase oxidization of the deposited sputter material.

30. The method of claim 19 further comprising adjusting a shape of an aperture positioned in a path of the sputtering flux to improve uniformity of the deposited sputtered material.

31. The method of claim 19 further comprising generating the reactive ion beam remotely from the vacuum chamber.

32. The method of claim 19 further comprising extracting the reactive ion beam through a grid so that the ions achieve a predetermined energy.

33. The method of claim 19 further comprising evacuating a volume of gas proximate to the sputter source.

34. The method of claim 19 further comprising collimating the sputtering flux to control a direction of the sputtering flux.

35. A sputtering system comprising:
a) a means for generating a reactive ion beam in a vacuum chamber from a reactant gas;
b) a means for containing an inert gas within a sputter source positioned inside the vacuum chamber so as to impede the reactant gas from entering into the sputter source;
c) a means for generating sputtering flux from the inert gas contained within the sputter source; and
d) a means for transporting a substrate through the reactive ion beam and through the sputtering flux in the sputter source, thereby reacting the reactive ions with deposited sputtered material.
